(19) United States
(12) Patent Application Publication
(10) Pub. No.: US 2025/0040157 A1
(43) Pub. Date: Jan. 30, 2025

(54) Metal-Oxide-Semiconductor Capacitors and Methods of Fabricating The Same

(71) Applicant: Taiwan Semiconductor Manufacturing Company, Ltd., Hsinchu (TW)

(72) Inventors: Wei-Liang Hsu, Hsinchu (TW); Chung-Lei Chen, Hsinchu (TW); Anhao Cheng, Hsinchu (TW); Yen-Liang Lin, Hsinchu (TW); Ru-Shang Hsiao, Hsinchu (TW)

(73) Assignee: Taiwan Semiconductor Manufacturing Company, Ltd., Hsinchu (TW)

(21) Appl. No.: 18/495,411

(22) Filed: Oct. 26, 2023

Related U.S. Application Data
(60) Provisional application No. 63/515,469, filed on Jul. 25, 2023.

(51) Int. Cl. H01L 29/94; H01L 29/66

(52) U.S. Cl. CPC H01L 29/94; H01L 28/91; H01L 28/92; H01L 29/66083

(57) ABSTRACT

A semiconductor structure includes a substrate and a capacitor over the substrate. The capacitor includes a silicide layer over the substrate. The capacitor includes a first dielectric layer over the silicide layer. The capacitor includes a metal gate structure over the first dielectric layer, where a top portion of the metal gate structure is over the substrate and a bottom portion of the metal gate structure extends into the substrate. The capacitor includes a second dielectric layer over the metal gate structure. The capacitor further includes a conductive structure over the second dielectric layer.

### CROSS-REFERENCE TO RELATED APPLICATION

This application is related to and claims priority to U.S. Provisional Application No. 63/515,469, filed on Jul. 25, 2023, titled “SEMICONDUCTOR CAPACITORS AND METHOD OF FABRICATING THE SAME,” the entire contents of which are incorporated herein by reference for all purposes.

### BACKGROUND

The semiconductor industry has experienced rapid growth due to continuous improvements in the integration density of a variety of electronic components (e.g., transistors, diodes, resistors, capacitors, etc.). For the most part, this improvement in integration density has come from repeated reductions in minimum feature size, which allows more components or devices to be integrated into a given area. While existing strategies of integrating capacitive devices, such as metal-oxide-semiconductor (MOS)-based capacitors, have been generally adequate, they have not been entirely satisfactory in all aspects. For example, it remains a challenge to meet improve device performance at reduced length scales to meet various targets for advanced devices.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1, 5, and 6 each illustrate a schematic top view of an example semiconductor device, in accordance with some embodiments.

FIGS. 2 and 3 each illustrate a schematic cross-sectional view of the example semiconductor device of FIG. 1 along line AA′, in accordance with some embodiments.

FIG. 4 illustrates a schematic cross-sectional view of the example semiconductor device of FIG. 1 along line BB′, in accordance with some embodiments.

FIG. 7 illustrates a schematic cross-sectional view of the example semiconductor device of FIG. 5 or 6 along line CC′, in accordance with some embodiments.

FIG. 8 illustrates a schematic cross-sectional view of the example semiconductor device of FIG. 5 or 6 along line CC′, in accordance with some embodiments.

FIG. 9 illustrates a schematic cross-sectional view of the example semiconductor device of FIG. 5 or 6 along line CC′, in accordance with some embodiments.

FIGS. 10A, 10B, and 10C each illustrate a flowchart of an example method of fabricating a semiconductor device, in accordance with some embodiments.

FIGS. 11, 12, 13, 14, 15, 16, 17, 18, 19, 20, 21, 22, and 23 each illustrate a schematic cross-sectional view of an example semiconductor device during intermediate stages of the example method of FIGS. 10A, 10B, and/or 10C, in accordance with some embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Metal-oxide-semiconductor (MOS) devices, such as MOS capacitors, and methods of fabricating the same is provided in the present disclosure. The intermediate stages of fabricating various embodiments of the present disclosure are illustrated. Throughout the various views and illustrative embodiments of the present disclosure, like reference numbers are used to designate like elements.

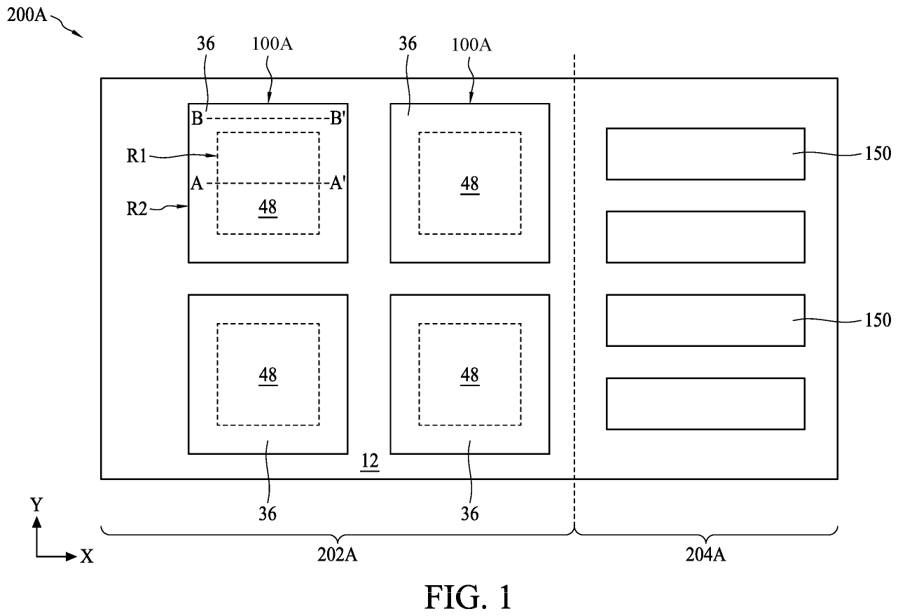

FIG. 1 illustrates a top view of an embodiment of a semiconductor structure 200A. The semiconductor structure 200A includes a device region 202A and a device region 204A, where the device region 202A includes a plurality of semiconductor devices 100A and the device region 204A includes a plurality of semiconductor devices 150. In the present embodiments, the semiconductor devices 100A include MOS devices, such as MOS capacitors, MOS transistors, the like, or combinations thereof. In some embodiments, the semiconductor devices 100A include MOS capacitors and are arranged in an array in the semiconductor structure 200A. In some embodiments, the semiconductor devices 150 include logic devices coupled to the array of the semiconductor devices 100A, for example.

Each semiconductor device 100A includes a first region R1 surrounded by a second region R2, where the regions R1 and R2 include different structures as described in detail below. The first region R1 includes at least a conductive structure (e.g., a conductive structure 48) over a substrate (e.g., a substrate 10) and the second region R2 includes a different metal structure (e.g., a metal structure 36) over the substrate. It is noted that portions of the semiconductor structure 200A are omitted from the subsequent figures for purposes of clarity. For example, interlayer dielectric (ILD) layer adjacent active features (e.g., metal gate structures) of the semiconductor structure 200A are omitted.

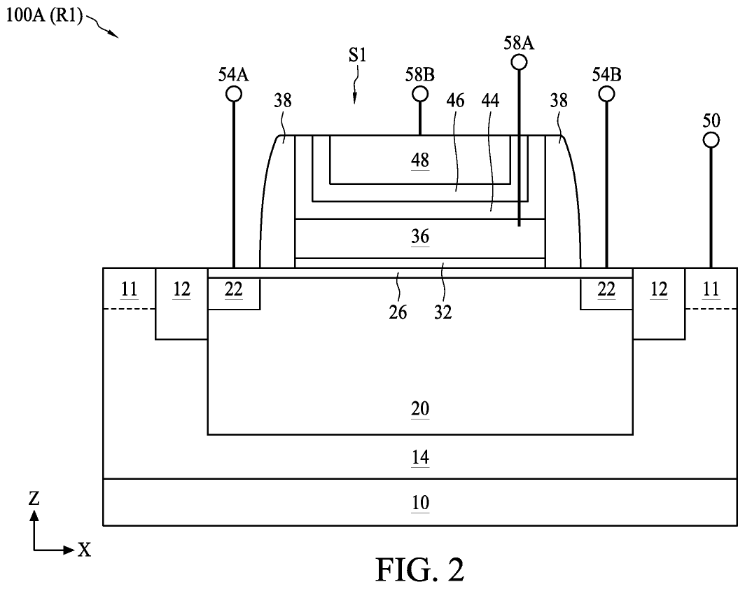

Referring to FIG. 2, which illustrates a cross-sectional view of the first region R1 of the semiconductor device 100A along line AA′ of FIG. 1, the semiconductor device 100A is provided over a substrate 10 and separated (or isolated) by isolation structures 12. The substrate 10 includes a semiconductor substrate, such as a bulk semiconductor, a semiconductor-on-insulator (SOI) substrate, or the like, which may be doped (e.g., with a p-type or an n-type dopant) or undoped. The substrate 10 may be a wafer, such as a silicon wafer. Generally, an SOI substrate includes a layer of a semiconductor material formed on an insulator layer. The insulator layer may be, for example, a buried oxide (BOX) layer, a silicon oxide layer, or the like. The insulator layer is provided on a substrate, typically a silicon or glass substrate. Other substrates, such as a multi-layered or gradient substrate may also be used. In some embodiments, the semiconductor material of the substrate 10 may include silicon; germanium; a compound semiconductor including silicon carbide, gallium arsenic, gallium phosphide, indium phosphide, indium arsenide, and/or indium antimonide; an alloy semiconductor including SiGe, GaAsP, AlInAs, AlGaAs, GaInAs, GaInP, and/or GaInAsP; or combinations thereof.

In some embodiments, the substrate 10 includes an intrinsic semiconductor material, such as intrinsic silicon. In some embodiments, the substrate 10 includes a semiconductor material doped with a suitable dopant according to a conductivity type of the semiconductor device 100A. For example, if the semiconductor device 100A is configured as an n-type device, then the substrate 10 may include an n-type dopant. Example n-type dopants include phosphorus, arsenic, the like, or combinations thereof, and example p-type dopants include boron, gallium, indium, the like, or combinations thereof.

Referring to FIG. 2, the semiconductor device 100A includes a doped well 14 disposed over or within the substrate 10, where the doped well 14 includes a dopant that has a conductivity type different from that of the semiconductor device 100A. For example, if the semiconductor device 100A is configured as an n-type device, then the doped well 14 includes a p-type dopant. In some embodiments, the doped well 14 extends across an entirety of the substrate 10 and is configured as a doped substrate of the semiconductor device 100A.

The semiconductor device 100A includes a doped layer (or impurity layer) 20 in the doped well 14. In the depicted embodiments where the semiconductor device 100A is configured as an n-type device, the doped layer 20 includes an n-type dopant. For embodiments in which the semiconductor device 100A is configured as a p-type device, the doped layer 20 includes a p-type dopant. In the present embodiments, the doped layer 20 is a heavily doped layer including an n-type dopant.

Referring to FIGS. 1 and 2, the semiconductor device 100A is surrounded by isolation structures 12. In some embodiments, each isolation structure 12 separates two adjacent doped layers and/or conductive features in the substrate 10. In some embodiments, the isolation structure 12 includes at least one dielectric layer having an oxide, such as silicon oxide (SiO and/or SiO2), a nitride, the like, or combinations thereof. In some embodiments, the isolation structure 12 includes a shallow trench isolation (STI) structure.

In some embodiments, the semiconductor device 100A further includes doped layers 11 adjacent the isolation structures 12. The doped layers 11 include one or more dopant of the same conductivity as the doped well 14 but at a higher concentration. For example, in the depicted embodiments, the doped well 14 includes a p-type dopant at a first concentration, and the doped layers 11 include the p-type dopant at a second concentration greater than the first concentration. In some embodiments, the doped layers 11 provide locations for coupling the substrate 10 and/or the doped well 14 to a contact 50, which is a substrate contact for the MOS capacitor structure of the semiconductor device 100A. In some embodiments, the doped layers 11 are optional and excluded from the semiconductor device 100A.

Still referring to FIG. 2, the semiconductor device 100A includes a pair of source/drain regions 22 in the doped layer 20. The source/drain regions 22 each include a dopant suitable for forming the semiconductor device 100A of a designated conductivity type. For example, the source/drain regions 22 in the depicted embodiments include an n-type dopant to form an n-type semiconductor device 100A. In the present embodiments, the source/drain regions 22 each include a dopant of the same conductivity type as the doped layer 20 but at a different concentration. For example, the concentration of the n-type dopant in the source/drain regions 22 is greater than that in the doped layer 20, such as by at least an order of magnitude.

In some embodiments, the source/drain regions 22 are formed adjacent to the isolation structures 12, where a bottom surface of each isolation structure 12 extends vertically to below a bottom surface of each source/drain region 22. In this regard, the source/drain regions 22 are electrically isolated from an adjacent device (e.g., another semiconductor device 100A in the array of the semiconductor structure 200A) by the isolation structures 12.

The semiconductor device 100A further includes a silicide layer 26 extending laterally across a top surface of the doped layer 20, including a top surface of each of the source/drain regions 22. In other words, sidewalls of the silicide layer 26 substantially coincide with sidewalls of the doped layer 20 that are laterally separated along the X axis. Furthermore, as depicted in FIG. 2, the silicide layer 26 is entirely over a top surface of the doped layer 20. In the depicted embodiments, the silicide layer 26 are laterally interposed between two opposing isolation structures 12. In the present embodiments, the silicide layer 26 includes a metal silicide material having at least one metal selected from Ti, W, Mo, Ni, Co, or the like. Other silicide materials may also be applicable to the present disclosure.

Still referring to FIG. 2, the semiconductor device 100A further includes a stack S1 of dielectric layers and conductive layers (or metal structures) over the silicide layer 26. In the present embodiments, the stack S1 includes a first dielectric layer 32, the metal structure 36, an interfacial layer 44, a second dielectric layer 46, and the conductive structure (e.g., metal structure) 48 arranged vertically along the Z axis stacked in such an order over the silicide layer 26. In the present embodiments, the stack S1 is entirely over the top surface of the doped layer 20. In other words, a bottommost surface of the stack S1, i.e., the first dielectric layer 32, is entirely above the top surface of the doped layer 20.

The semiconductor device 100A includes gate spacers 38 extending along sidewalls of the stack S1. The gate spacers 38 may include a suitable dielectric material, such as silicon oxide, silicon oxycarbonitride, silicon nitride, silicon oxynitride, silicon carbonitride, the like, or combinations thereof. The gate spacers 38 may include one or more layers of the suitable dielectric materials.

In the present embodiments, the stack S1 includes a first dielectric layer 32 over the silicide layer 26. In the present embodiments, the first dielectric layer 32 laterally extends across a portion of the silicide layer 26 interposed between the source/drain regions 22. In some embodiments, the first dielectric layer 32 is configured as a gate dielectric layer. As such, the first dielectric layer 32 may include any suitable dielectric material, such as silicon oxide, silicon nitride, a high-k dielectric material (i.e., having a dielectric constant greater than that of silicon oxide, which is about 3.9), the like, or combinations thereof. The high-k dielectric material may include an oxide or a silicate of Hf, Al, Y, Zr, La, Mg, Ba, Ti, Pb, the like, or combinations thereof. The high-k dielectric material may additionally or alternatively include a compound oxide, such as a compound of ZrO₂, Al₂O₃, and ZrO₂ (ZₐA_{b}Z_{c}, where a, b, and c satisfy a suitable stoichiometric relationship), a compound of Al₂O₃, ZrO₂, Al₂O₃(AₐZ_{b}A_{c}, where a, b, and c satisfy a suitable stoichiometric relationship), or a compound of ZrO₂, Al₂O₃, ZrO₂, Al₂O₃, ZrO₂ (ZₐA_{b}Z_{c}A_{d}Zₑ, where a, b, c, d, and e satisfy a suitable stoichiometric relationship). In some embodiments, the first dielectric layer 32 has a multi-layered structure.

The stack S1 includes a metal structure 36 over the first dielectric layer 32. In the present embodiments, the metal structure 36 is configured as a metal gate structure. Accordingly, the metal structure 36 includes at least a metal gate electrode. In some embodiments, though not depicted separately, the metal gate structure further includes one or more work function metal layers, each having a compound metal or a single metal. The metal gate electrode includes any suitable metal, such as tungsten (W), copper (Cu), ruthenium (Ru), aluminum (Al), gold (Au), cobalt (Co), the like, or combinations thereof. The work function metal layer may include an n-type work function metal with a work function in a range of about 3.9 to about 4.5, a p-type work function metal with a work function in a range of about 4.5 to about 5.2, or a combination thereof. Examples of the work function layers include TIN, TaN, Ru, Mo, Al, W, HfN, Ir, Pt, PtSi, MON, ZrSi₂, MoSi₂, NiSiₓ, WN, Ti, Ta, Ag, TaSiₓ, TaAl, TaAlC, TiAlN, TaC, TaCN, TaSiN, Mn, Zr, and the like. The metal gate electrode may be formed over the one or more work function metal layers. In some embodiments, the metal structure 36 does not include any work function metal layer. As such, the metal structure 36 only includes the metal gate electrode. In some embodiments, the metal structure 36 includes additional layers, such as a capping layer, a glue layer, the like, or combinations thereof.

The stack S1 further includes an interfacial layer 44 and a second dielectric layer 46 over the metal structure 36. In the present embodiments, the interfacial layer 44 and the second dielectric layer 46 are each formed to a U shape that includes sidewalls extending along the gate spacers 38. In other words, the sidewalls of the interfacial layer 44 are vertically aligned with sidewalls of the metal structure 36.

In some embodiments, the second dielectric layer 46 is configured as a gate dielectric layer. As such, the second dielectric layer 46 may include any suitable dielectric material, such as silicon oxide, silicon nitride, a high-k dielectric material provided herein, the like, or combinations thereof. In some embodiments, the second dielectric layer 46 has the same composition as the first dielectric layer 32. In some embodiments, the second dielectric layer 46 has a different composition from the first dielectric layer 32. In some embodiments, the interfacial layer 44 includes an oxide, such as silicon oxide. In the present embodiments, the interfacial layer 44 includes a dielectric material having a lower dielectric constant (i.e., k value) than a dielectric material included in the second dielectric layer 46. For example, the interfacial layer 44 may include silicon oxide, which has a dielectric constant less than about 3.9, and the second dielectric layer 46 may include a high-k dielectric material, such as a metal oxide or a metal silicide, which has a dielectric constant greater than about 3.9. In some embodiments, the interfacial layer 44 is optional.

Furthermore, still referring to FIG. 2, the stack S1 includes a conductive structure 48 over the second dielectric layer 46, where the second dielectric layer 46 surrounds a bottom and sidewall surfaces of the conductive structure 48. In the depicted embodiments, a top surface of the conductive structure 48 is substantially coplanar with a top surface of each of the second dielectric layer 46, the interfacial layer 44, and the gate spacers 38. In some embodiments, the conductive structure 48 is configured as a metal gate structure, similar to the metal structure 36 described in detail above. For example, the conductive structure 48 includes at least a metal gate electrode and one or more work function metal layers described in detail above with respect to the metal structure 36. In some embodiments, the conductive structure 48 includes the metal gate electrode but does not include any work function metal layer. Accordingly, the conductive structure 48 is alternatively referred to as the metal structure 48 in some embodiments. In some embodiments, the conductive structure 48 includes conductive polysilicon instead of a metal.

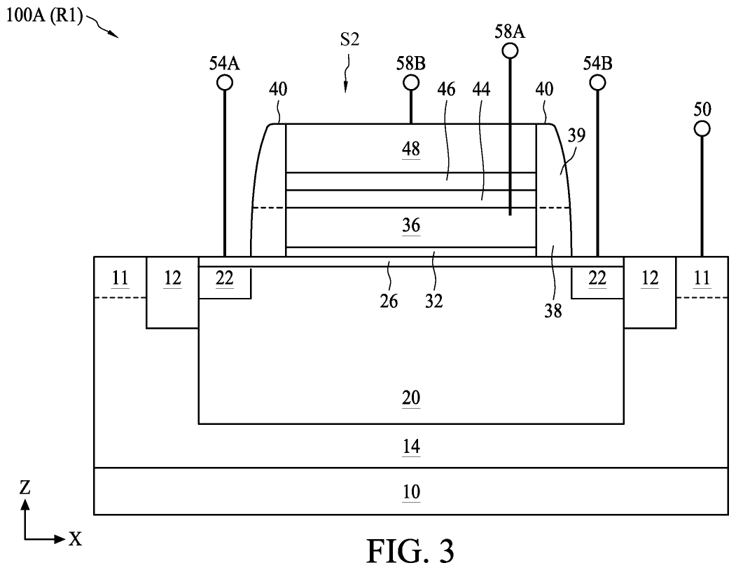

In some embodiments, portions of the semiconductor device 100A in the first region R1 are arranged differently from that depicted in FIG. 2. For example, referring to FIG. 3, the semiconductor device 100A includes a stack S2 that is arranged in a manner similar to the stack S1. In the stack S2, the interfacial layer 44 and the second dielectric layer 46 do not include any portions that extend along the gate spacers 38, such that their sidewalls are vertically aligned with those of the metal structure 36 and the conductive structure 48. Furthermore, the gate spacers 38 are formed to surround only the sidewalls of the metal structure 36, and additional gate spacers 39 are formed to extend along the sidewalls of the stack S2, which includes the interfacial layer 44, the second dielectric layer 46, and the conductive structure 48. As depicted, the gate spacers 38 and the gate spacers 39 are stacked together and vertically aligned with one another to form gate spacers 40.

In the present embodiments, such as that depicted in FIG. 2, the combination of the silicide layer 26 and the stack S1 in the first region R1 of the semiconductor device 100A provides an MOS capacitor having an “M₁I₁M₂I₂M₃” stacked structure, where M₁, M₂, and M₃ each denote a conductive plate (or conductive layer, metal layer, metal plate) and I₁ and I₂ each denote an insulator (or dielectric layer). Accordingly, the semiconductor device 100A provides two MOS capacitors, a first capacitor M₁I₁M₂ and a second capacitor M₂I₂M₃ connected in parallel. A composite capacitance C_{comp} of the MOS capacitor provided in the first region R1 of the semiconductor device 100A is a sum of a capacitance of the first capacitor M₁I₁M₂ and a capacitance of the second capacitor M₂I₂M₃.

In the present embodiments, the conductive plate M₁ corresponds to the silicide layer 26, the dielectric layer I₁ corresponds to the first dielectric layer 32, the conductive place M₂ corresponds to the metal structure 36, the dielectric layer I₂ corresponds to the second dielectric layer 46 (and the interfacial layer), and the conductive plate M₃ corresponds to the conductive structure 48. In existing technologies, an MOS capacitor generally has an “M₁IM₂” structure, where “M₁” typically corresponds to a semiconductor substrate of the MOS capacitor, “I” typically corresponds to an insulator (e.g., an oxide-containing gate dielectric layer), and “M₂” typically corresponds to a metal gate structure. Accordingly, forming an additional insulator (e.g., the second dielectric layer 46 and/or the interfacial layer 44) and an additional conductive plate (e.g., the conductive structure 48) in the stack S1, and forming a silicide layer (e.g., the silicide layer 26) underlying and in contact with the stack S1, provides means of increasing a capacitance of the MOS capacitor in a compact design, thereby improving the performance of the device without substantially enlarging the planar dimensions of the device.

In some embodiments, the semiconductor device 100A in the first region R1 further includes a plurality of contacts configured to couple components of the device with subsequently formed interconnect features (not depicted). For example, as depicted in FIG. 2, the semiconductor device 100A may include source/drain contacts 54A and 54B coupled to a respective source/drain region 22 and gate contacts 58A and 58B each coupled to the metal structure 36 and the conductive structure 48, respectively. In some embodiments, the source/drain contacts 54A and 54B are coupled to the contact 50, which is electrically coupled to the doped well 14 (e.g., the doped layers 11).

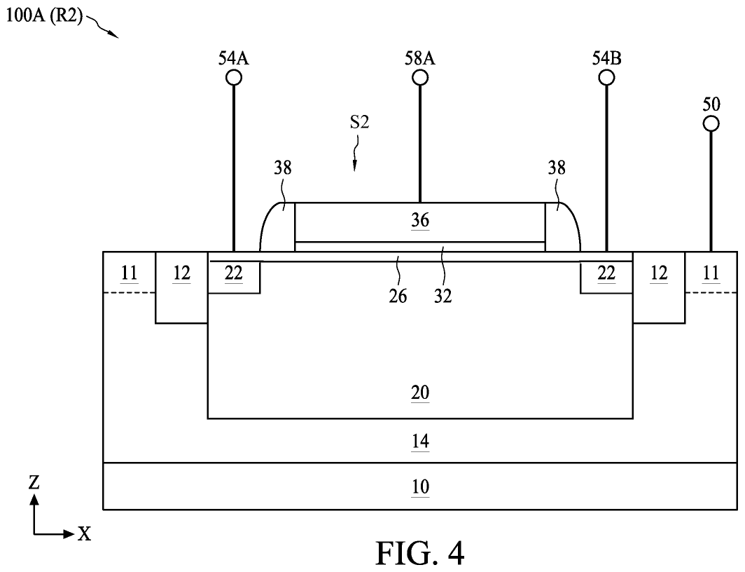

Referring to FIGS. 1 and 4, which illustrates a cross-sectional view of the second region R2 of the semiconductor device 100A along line BB′ of FIG. 1, the second region R2 includes a stack S3 disposed over the silicide layer 26, where the stack S3 only includes the first dielectric layer 32 and the metal structure 36 but does not include the second dielectric layer 46, the interfacial layer 44, or the conductive structure 48. In this regard, the stack S3 forms an MOS capacitor with a stacked structure of M₁IM₂ with the silicide layer 26. In some embodiments, the stack S3 allows the gate contact 58A be coupled to the metal structure 36.

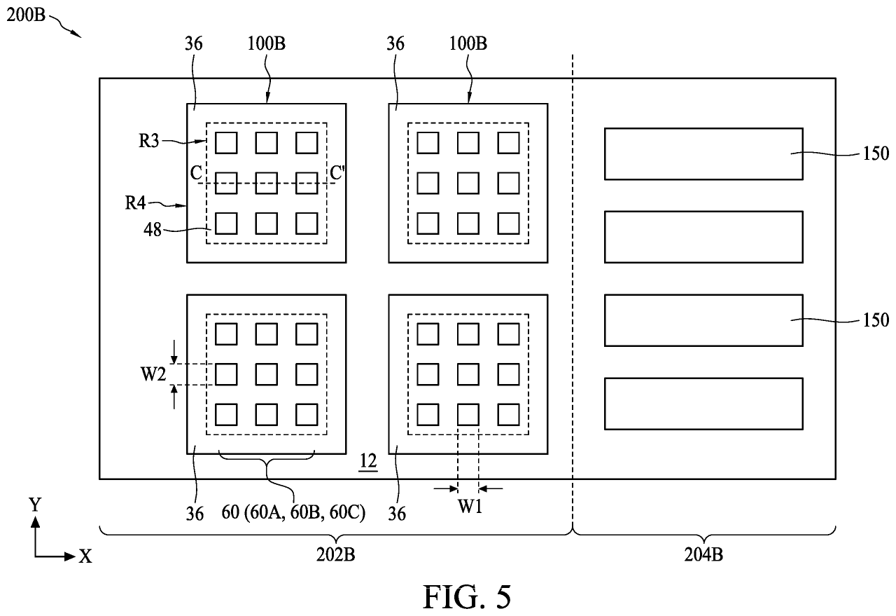

FIG. 5 illustrates a top view of an embodiment of a semiconductor structure 200B. The semiconductor structure 200B includes a device region 202B and a device region 204B, where the device region 202B includes a plurality of semiconductor devices 100B and the device region 204B includes a plurality of the semiconductor devices 150 as described above. In the present embodiments, the semiconductor devices 100B include MOS capacitors similar in structure to those of the semiconductor devices 100A described above.

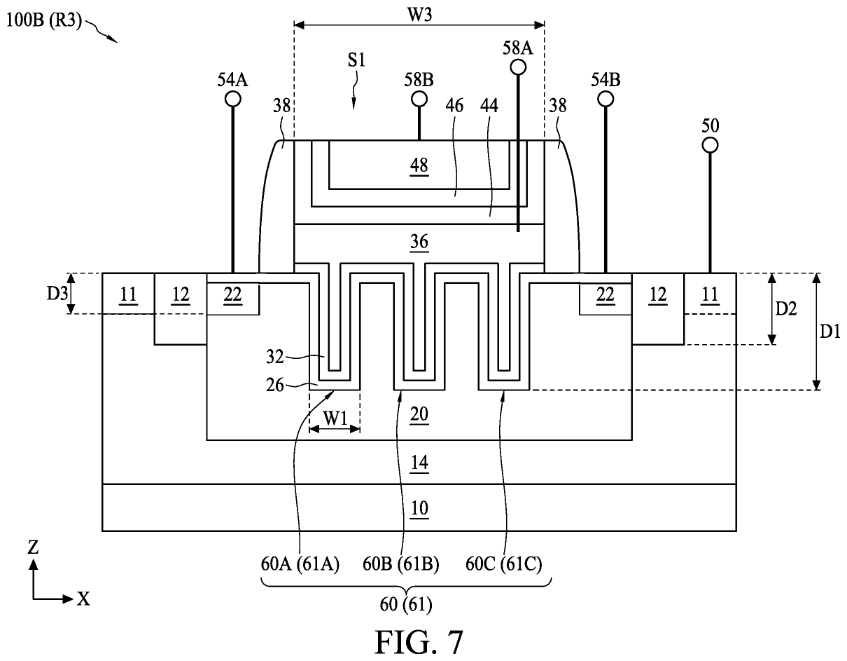

Each semiconductor device 100B includes a third region R3 surrounded by a fourth region R4 different from the third region R3 in structure, similar to the manner in which the first region R1 is surrounded by the second region R2 in the semiconductor device 100A. For example, as depicted in FIGS. 5 and 7, which illustrates a cross-sectional view of the third region R3 along line CC′ of FIG. 5, the third region R3 includes the conductive structure 48 over the substrate 10 and the fourth region R4 includes the metal structure 36 over the substrate 10.

However, different from the semiconductor device 100A, the third region R3 of the semiconductor device 100B includes a plurality of embedded structures 60A, 60B, and 60C, collectively referred to as the embedded structures 60, in the doped layer 20. Referring to FIGS. 5 and 7, bottom portions of the silicide layer 26 and bottom portions of the stack S1, which include portions of the first dielectric layer 32 and the metal structure 36, extend into the doped layer 20 to form the embedded structures 60. In this regard, the embedded structures 60 resemble columns enclosed in or surrounded by the doped layer 20.

In the present embodiments, the embedded structures 60A-60C provide additional surface area for at least one of the conductive plates M₁, M₂, and M₃ in the MOS capacitor with the stacked structure M₁I₁M₂I₂M₃ described in detail above. For example, referring to FIG. 7, the embedded structures 60 increase a surface area of the silicide layer 26, corresponding to M₁, and a metal structure 36, corresponding to M₂. As described above, the composite capacitance C_{comp} of the MOS capacitor with the stacked structure M₁I₁M₂I₂M₃ is the sum of the capacitance of the first capacitor M₁I₁M₂ and the capacitance of the second capacitor M₂I₂M₃. Accordingly, by vertically extending the silicide layer 26 and portions of the stack S1 into the doped layer 20 to form the embedded structures 60, the surface areas of the conductive plates M₁ and M₂ are enlarged, thereby increasing the capacitance of the first capacitor M₁I₁M₂, and thus the composite capacitance C_{comp} of the MOS capacitor with the stacked structure M₁I₁M₂I₂M₃.

In the depicted embodiments, still referring to FIG. 7, the embedded structures 60 each include a depth D1 along the Z axis, a first width W1 along the X axis, and a second width W2 along the Y axis. In some embodiments, the depth D1 is substantially greater than at least the first width W1. In the present embodiments, the embedded structures 60 do not penetrate through the doped layer 20, such that the depth D1 is less than a depth of the doped layer 20. In some examples, the depth D1 may be greater than 0 and less than about 300 nm. In some embodiments, the smaller one of the first width W1 and the second width W2, also known as a critical dimension (CD) of the semiconductor device 100B, is at least about 40 nm. In some embodiments, sidewalls of the silicide layer 26, the first dielectric layer 32, and the metal structure 36 in each embedded structure 60 are substantially vertical along the Z axis, i.e., exhibiting little to no lateral deviations along the X axis. In some embodiments, the increase in the composite capacitance C_{comp} is tuned by adjusting the dimensions of the embedded structures 60. For example, increasing the depth D1, the first width W1, the second width W2, or combinations thereof, can increase the composite capacitance C_{comp} of the MOS capacitor.

In some embodiments, an aspect ratio (AR), defined as a ratio of the depth D1 to the width W1 of each of the embedded structures 60 is about 1 and to about 10. In some embodiments, an increase in the AR of the embedded structure 60 generally yields a higher capacitance between the conductive plates M₁ and M₂ (i.e., the silicide layer 26 and the metal structure 36). However, if the AR is too large (e.g., significantly greater than about 10), it may become challenging to obtain trenches with the desired dimensions due to limitations associated with the photolithography and etching processes used to form such trenches.

In some embodiments, the depth D1 is greater than a depth D2 of the isolation structures 12, which is greater than a depth D3 of the source/drain regions 22. In some embodiments, the depth D1 may be less than the depth D2. In some embodiments, the embedded structures 60 are formed to have different depths (e.g., the depth D1), different widths (e.g., the first width W1 and/or the second width W2), or both. In addition, although three embedded structures 60 are depicted, the number of the embedded structures 60 may vary between one and ten, inclusive. In some embodiments, the number of the embedded structures 60 is determined based on a width W3 of the stack S1 along the X axis, where the embedded structures 60 are spaced along the width W3. A greater number of the embedded structures 60 may be applicable so long as the dimensions of each embedded structure 60 are permitted by design rules for a given width W3 of the stack S1 and not too high to negatively impact the processes of fabricating components of the semiconductor device 100B including, for example, a metal filling (or deposition) process.

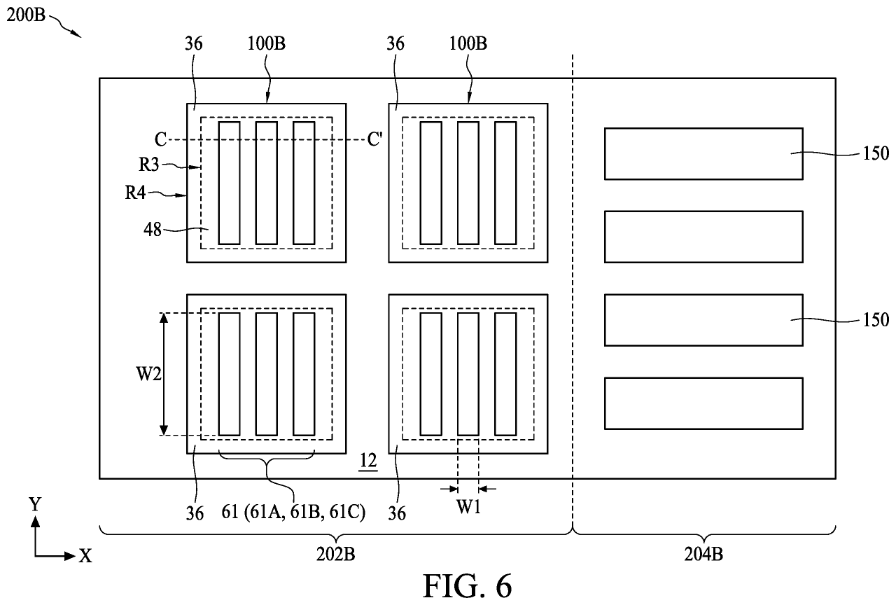

In some embodiments, referring to FIG. 5, the embedded structure 60 each have a pillar configuration, where the widths W1 and W2 are similar or substantially the same, such that the embedded structures 60 each have a square shape in a top view. In some embodiments, referring to FIG. 6, the semiconductor device 100B includes embedded structures 61A, 61B, and 61C, collectively referred to as the embedded structures 61, each having a configuration different from that of the embedded structure 60. For example, the embedded structures 61 each have a beam configuration, where the second width W2 is substantially greater than the first width W1, such that the embedded structures 61 each have an elongated shape (e.g., a rectangular shape) in the top view. In this regard, the embedded structure 61 are elongated along a length of the conductive structure 48 (e.g., along the Y axis in FIG. 6) and spaced along the width W3 of the conductive structure 48 (e.g., along the X axis in FIG. 7) in the third region R3. It is noted that, since the embedded structures 60 and 61 are illustrated to have the same first width W1 as depicted in FIGS. 5 and 6, respectively, FIG. 7 also depicts the embodiment of the semiconductor device 100B that includes the embedded structures 61 in a cross-sectional view along line CC′ of FIG. 6.

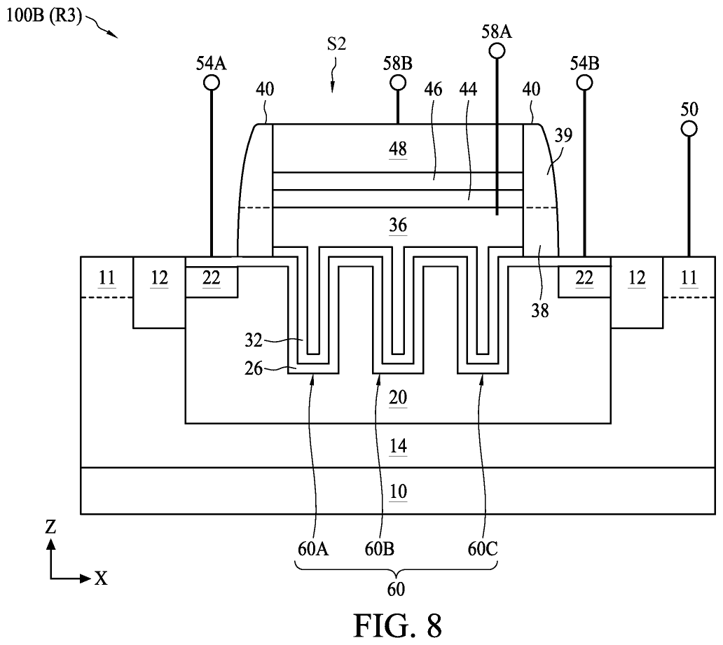

FIG. 8 illustrates an embodiment of the semiconductor device 100B in the region R3 that is similar to the embodiment depicted in FIG. 7. However, the semiconductor device 100B depicted in FIG. 8 includes the additional gate spacers 39 extending from the gate spacers 38 and contacting the sidewalls of the interfacial layer 44, the second dielectric layer 64, and the conductive structure 48. In this regard, the embodiment of the semiconductor device 100B depicted in FIG. 7 is analogous to the embodiment of the semiconductor device 100A depicted in FIG. 2, and the embodiment of the semiconductor device 100B depicted in FIG. 8 is analogous to the embodiment of the semiconductor device 100A depicted in FIG. 3.

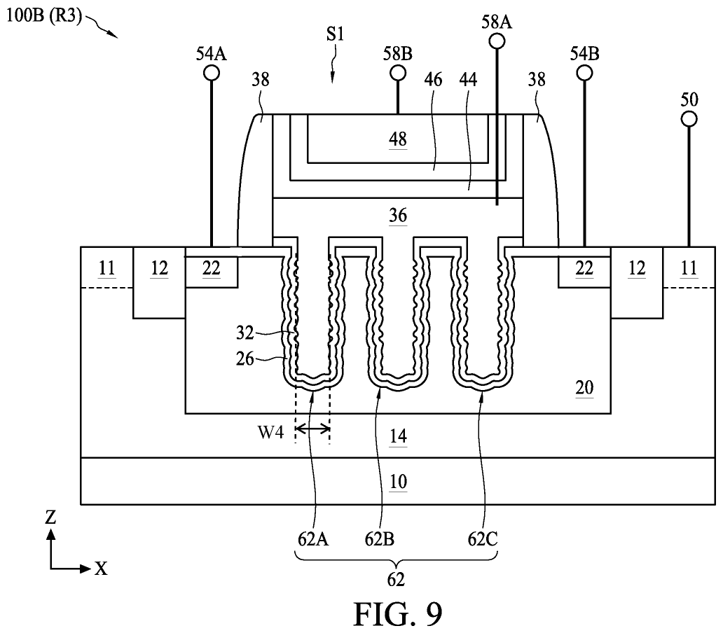

In some embodiments, referring to FIG. 9, an embodiment of the semiconductor device 100B includes embedded structures 62A, 62B, and 62C, collectively referred to as the embedded structures 62, that are similar to the embedded structures 60 with the exception that surfaces of the doped layer 20 in contact with the embedded structures 62 exhibit roughness and corrugation. In this regard, portions of the sidewalls of the silicide layer 26, the first dielectric layer 32, and the metal structure 36 in each embedded structure 62 extend or deviate laterally towards the doped layer 20 as depicted in FIG. 9. In some non-limiting examples, such extension or deviation may be less than about 10% of a width W4 (e.g., along the X axis) of the metal structure 36 in the embedded structure 62, where the width W4 is defined between two mean lines extending vertically (e.g., along the Z axis) through the surface roughness on the opposing sidewalls of the metal structure 36. In some embodiments, such surface roughness causes portions of the metal structure 36 to be embedded in the first dielectric layer 32 along sidewalls of the embedded structures 62. In the present embodiments, the surface roughness of the embedded structures 62 are configured to further increase the surface areas of the conductive plates M₁ and M₂, which together increase the capacitance of the first capacitor M₁I₁M₂ in comparison to the embedded structures 60.

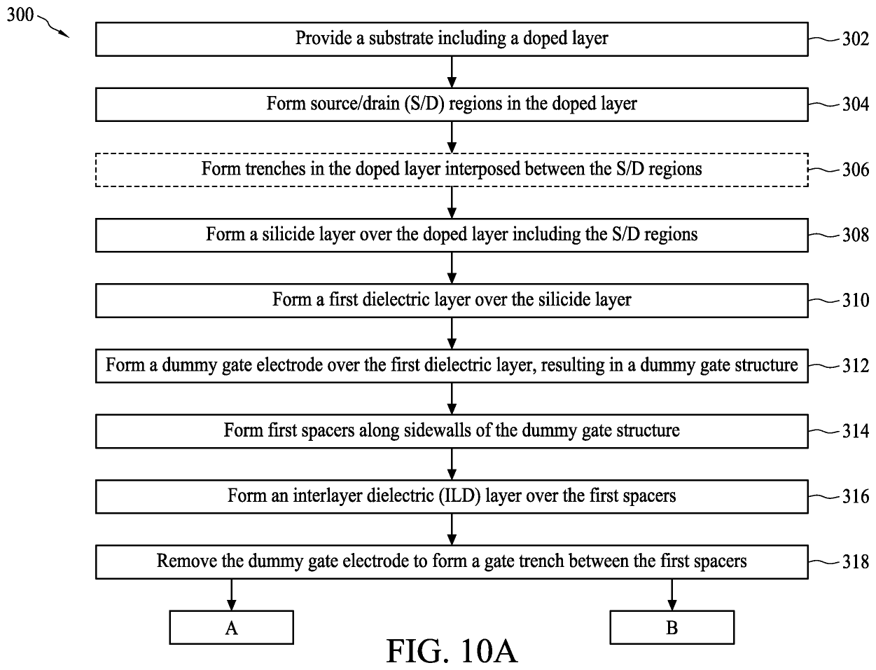

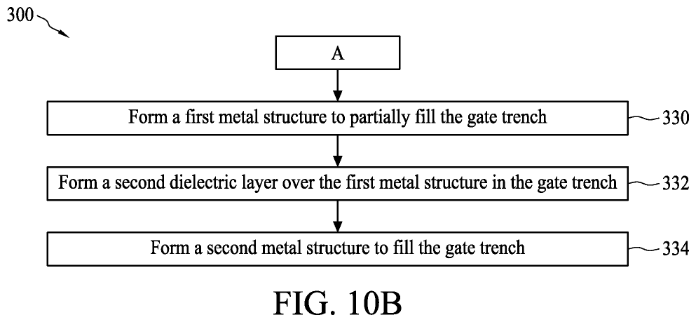

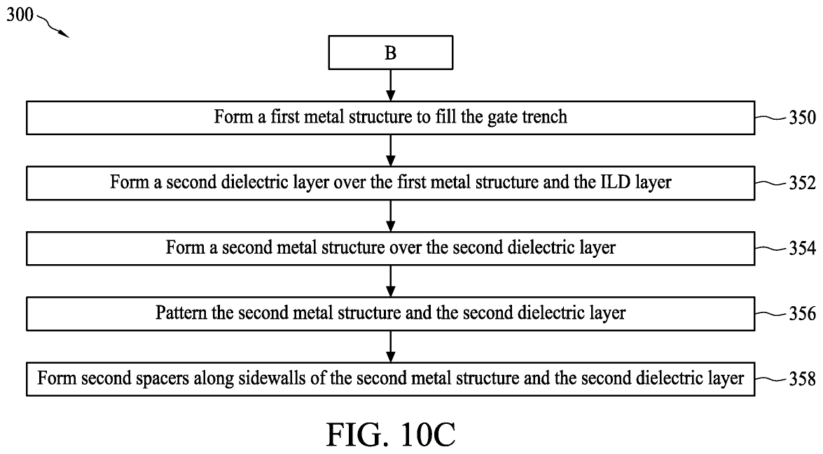

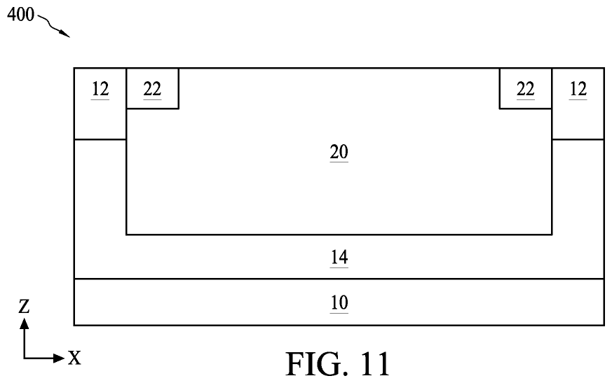

FIGS. 10A-10C illustrate a flowchart of a method 300 to form a semiconductor device 400, according to one or more embodiments of the present disclosure. The semiconductor device 400 may be similar, in portion or entirety, to the semiconductor devices 100A and 100B as described in detail above. In this regard, the method 300 is applicable for forming at least portions of the semiconductor devices 100A and 100B, such as forming the first region R1 of the semiconductor device 100A and the third region R3 of the semiconductor device 100B. In some embodiments, operations of the method 300 may be associated with cross-sectional views of the semiconductor device 400 in a plane defined by axes X and Z at various fabrication stages as depicted in FIGS. 11-23. It is noted that the method 300 is merely an example and is not intended to limit the present disclosure. Accordingly, it should be understood that additional operations may be provided before, during, and after the method 300 of FIGS. 10A-10C, and that some other operations may only be briefly described herein.

Referring to FIGS. 10A and 11, the substrate 10 is provided for the semiconductor device 400 at operation 302.

In some embodiments, as depicted in FIG. 11, the doped well 14 is first formed in the substrate 10 at operation 302, where the doped well 14 includes a dopant that has a conductivity type different from that of the semiconductor device 400. Subsequently, still referring to FIGS. 10A and 11, the doped layer (or impurity layer) 20 is formed in the doped well 14 such that the doped well 14 surrounds a bottom surface and sidewall surfaces of the doped layer 20.

In some embodiments, the doped layer 20 is formed by performing a series of patterning and doping processes. For example, a patterned mask layer (not depicted) may be formed over the doped well 14 to expose portions of the doped well 14. The patterned mask layer may include a photoresist material that can be patterned using photolithography techniques. Generally, photolithography techniques utilize the photoresist material that is deposited, irradiated (or exposed), and developed to remove a portion of the photoresist material. The remaining photoresist material, which forms the patterned mask layer, protects the underlying material from subsequent processing steps, such as doping or etching. The patterned mask layer may alternatively or additionally include a dielectric material, such as an oxide, that is patterned by the photolithography techniques, for example. A doping process is then performed to the exposed portion(s) of the doped well 14 to form the doped layer 20. The doping process may be an implantation process, a diffusion process, or the like. After performing the doping process, the patterned mask is removed from the semiconductor device 400 by any suitable process, such as plasma ashing or resist stripping.

Still referring to FIG. 11, a plurality of the isolation structures 12 are formed adjacent to the doped layer 20 in the doped well 14 at operation 302. The isolation structures 12 may be formed by patterning a mask layer (not depicted) to expose portions of the doped well 14 between adjacent doped layers 20. The mask layer may be patterned by photolithography process similar to that described above with respect to forming the doped layer 20, followed by an etching process using the patterned mask layer as an etch mask to form trenches (not depicted) penetrating the doped well 14. The etching process may include dry etching, wet etching, reactive ion etching (RIE), the like, or combinations thereof. Subsequently, the at least one dielectric layer is deposited in the trenches by any suitable process, such as high-density plasma CVD (HDPCVD), flowable CVD (FCVD) (e.g., a CVD-based material deposition in a remote plasma system, followed by an annealing or curing process to densify the deposited material into another material, such as an oxide), spin coating, the like, or combinations thereof. Other dielectric materials and/or other formation processes may be used to form the isolation structures 12. Subsequently, a planarization process, such as a chemical-mechanical polish/planarization (CMP) process, may be performed to remove any excess material of the at least one dielectric layer. The patterned mask layer may also be removed by the planarization process or by any other suitable process.

In some embodiments, the doped layers 11 (see FIGS. 2-4, for example) are subsequently formed adjacent to the isolation structures 12 in the doped well 14. The doped layers 11 may be formed by a series of patterning and doping processes similar to that describe above with respect to forming the doped layer 20. In some embodiments, the doped layers 11 are omitted.

Referring to FIGS. 10A and 11, the source/drain regions 22 are formed in the doped layer 20 at operation 304. The source/drain regions 22 may be formed by any suitable doping process, such as an implantation process or a diffusion process. In some embodiments, a patterned mask layer (not depicted) is first formed over the substrate 10 to expose portions of the doped layer 20 corresponding to locations of the source/drain regions 22. The method of forming the patterned mask layer is similar to that described above with respect to that of the patterned mask layer used in forming the doped layer 20. Subsequently, a suitable doping process is performed to introduce the n-type dopant to the exposed portions of the doped layer 20, resulting in the source/drain regions 22. After performing the doping process, the patterned mask layer is removed by any suitable process described herein.

In some embodiments, though not depicted, forming the source/drain regions 22 includes a series of etching and epitaxial processes. For example, portions of the doped layer 20 corresponding to the locations of the source/drain regions 22 are first removed in an etching process (using a patterned mask, for example) to form source/drain recesses. Subsequently, one or more epitaxial processes are performed to grow the source/drain regions 22 in the source/drain recesses. The epitaxial growth processes may be implemented using any suitable process, such as metal-organic CVD (MOCVD), molecular beam epitaxy (MBE), liquid phase epitaxy (LPE), vapor phase epitaxy (VPE), selective epitaxial growth (SEG), the like, or combinations thereof.

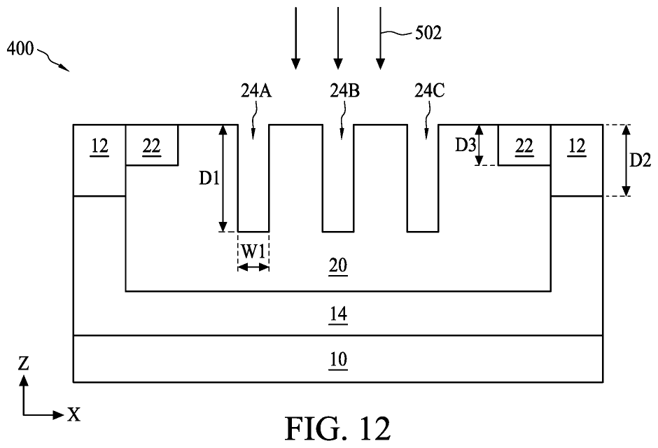

Referring to FIGS. 10A and 12, trenches 24A, 24B, and 24C are formed in the doped layer 20 at operation 306.

In the present embodiments, the trenches 24A-24C are formed in a region of the doped layer 20 between the source/drain regions 22 along the X axis, where each of the trenches 24A-24C are embedded in the doped layer 20. In this regard, the trenches 24A-24C do not extend through an entire thickness of the doped layer 20, such that a bottom surface of each of the trenches 24A-24C is separated from the underlying doped well 14 by a portion of the doped layer 20.

In some embodiments, the trenches 24A-24C are formed to each have the first width W1 along the X axis, the second width W2 along the Y axis (see FIGS. 5 and 6, for example) and the depth D1 along the Z axis. In some embodiments, the first width W1, also known as a critical dimension (CD) of the semiconductor device 400, is at least about 40 nm. In some embodiments, the trenches 24A-24C are formed to have different depths, different widths, or both. In addition, although three trenches are depicted in FIG. 12, the number of trenches may vary between one and ten, inclusive. A higher number of trenches may be possible so long as the number of trenches is permitted by design rules and not too high to negatively impact subsequent operations of the method 300, such as a metal filling (or deposition) process. In some embodiments, the trenches 24A-24C are formed in a pillar configuration to provide the embedded structures 60 as depicted in FIG. 5. In some embodiments, the trenches 24A-24C are formed to in a beam configuration to provide the embedded structures 61 as depicted in FIG. 6.

The trenches 24A-24C may be formed by a series of patterning and etching processes. For example, a patterned mask (not depicted) including openings corresponding to positions of the trenches 24A-24C is formed over the semiconductor device 400. The method of forming such a patterned mask is similar to that described above with respect to that of the patterned mask layer used in forming the doped layer 20. Portions of the doped layer 20 are then removed by a suitable etching process 502, such as a dry etching process (or plasma etching process), using the patterned mask layer as an etch mask. The duration of the etching process 502 may be controlled to form the trenches 24A-24C to the depth D1. After forming the trenches 24A-24C, the patterned mask layer is removed from the semiconductor device 400 by any suitable process, such as plasma ashing or resist stripping.

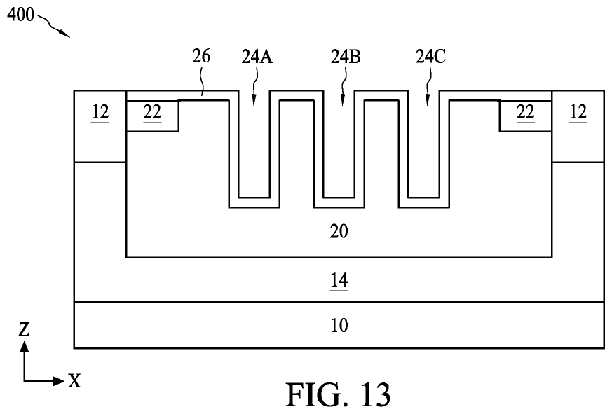

Referring to FIGS. 10A and 13, the silicide layer 26 is formed over the doped layer 20, including over the source/drain regions 22 at operation 308.

In the present embodiments, the silicide layer 26 is formed over the silicon-containing semiconductor surfaces of the semiconductor device 400. For example, the silicide layer 26 is formed over a top surface of the doped layer 20, sidewall and bottom surfaces of the doped layer 20 exposed in the trenches 24A-24C, and the source/drain regions 22. In this regard, the silicide layer 26 is not formed over the isolation structures 12.

The silicide layer 26 may be formed by any suitable process. For example, the silicide layer 26 may be formed by depositing a metal-containing precursor in the presence of a gas using a suitable deposition technique, such as CVD. In some embodiments, the deposition process is implemented at an elevated temperature. The metal-containing precursor may include TiCl₄, WCl₅, MoCl₅, Ni(CO)₄, Co₂(CO₆) [HCC(C(CH₃)₃)], the like, or combinations thereof, and the gas may include hydrogen (H2), argon (Ar), or a combination thereof. The deposited metal-containing precursor subsequently reacts with silicon in the doped layer 20 and the source/drain regions 22 to form the silicide layer 26. Any unreacted metal, such as Ti, W, Mo, Ni, Co, or the like, from the metal-containing precursor may be removed after completing the silicidation process.

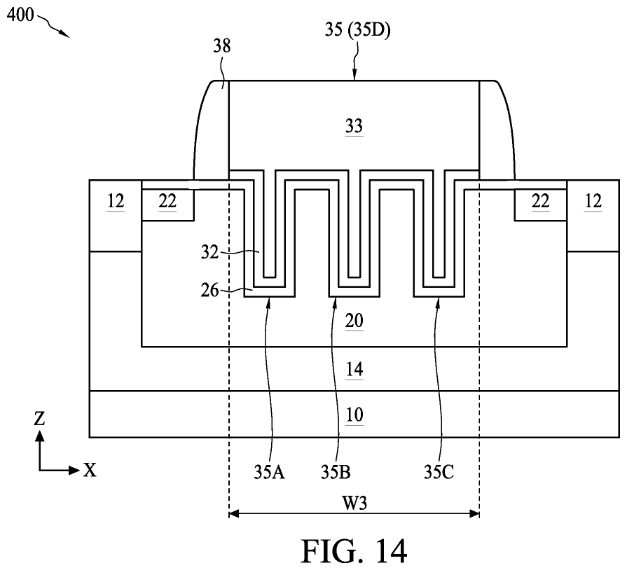

Referring to FIGS. 10A and 14, the first dielectric layer 32 is formed over the substrate 10 at operation 310.

In the present embodiments, the first dielectric layer 32 is deposited as a blanket layer (not depicted) over the semiconductor device 400. For example, portions of the first dielectric layer 32 are formed over the silicide layer 26 both inside and outside the trenches 24A-24C. In this regard, the first dielectric layer 32 and the silicide layer 26 partially fill the trenches 24A-24C. The first dielectric layer 32 may be formed by any suitable deposition technique, such as chemical oxidation, thermal oxidation, CVD, atomic layer deposition (ALD), physical vapor deposition (PVD), the like, or combinations thereof.

Referring to FIGS. 10A and 14, a dummy gate structure 35 including the first dielectric layer 32 and a dummy gate electrode 33 is formed over the trenches 24A-24C at operation 312.

The dummy gate electrode 33 may include any suitable material, such as a polysilicon layer, and may be formed over the semiconductor device 400 as a blanket layer (not depicted). In the present embodiments, the dummy gate electrode 33 completely fills the trenches 24A-24C as depicted in FIG. 14.

Subsequently, the dummy gate electrode 33 and the first dielectric layer 32 are patterned to form the dummy gate structure 35. The dummy gate structure 35 may be formed by a series of patterning and etching processes similar to that used for forming the trenches 24A-24C. For example, a patterned mask layer (not depicted) is first formed over the dummy gate electrode 33 as an etch mask. An etching process, such as a dry etching process or a wet etching process, is implemented to remove portions of the dummy gate electrode 33 and the first dielectric layer 32 exposed by the patterned mask layer, with the dummy gate structure 35 remaining over the doped layer 20. After performing the etching process, the patterned mask layer is removed by any suitable process, such as plasma ashing or resist stripping.

In the present embodiments, the dummy gate structure 35 is interposed between the source/drain regions 22 and laterally (e.g., along the X axis) extends over the trenches 24A-24C for a width W3. Accordingly, the dummy gate structure 35 includes a top portion 35D over bottom portions 35A, 35B, and 35C, which correspond to the trenches 24A, 24B, and 24C, respectively. In this regard, the bottom portions 35A-35C are extensions of the dummy gate structure 35 embedded in the doped layer 20.

Referring to FIGS. 10A and 14, the gate spacers 38 are formed along sidewalls of the dummy gate electrode 33 at operation 314.

The gate spacers 38 may be formed by first conformally depositing a dielectric layer over the dummy gate structure 35 using any suitable deposition process, such as thermal oxidation, CVD, or the like, and subsequently removing portions of the dielectric layer using a suitable etching process, such as a directional or anisotropic dry etching process, leaving behind the gate spacer 38 along sidewalls of the dummy gate structure 35.

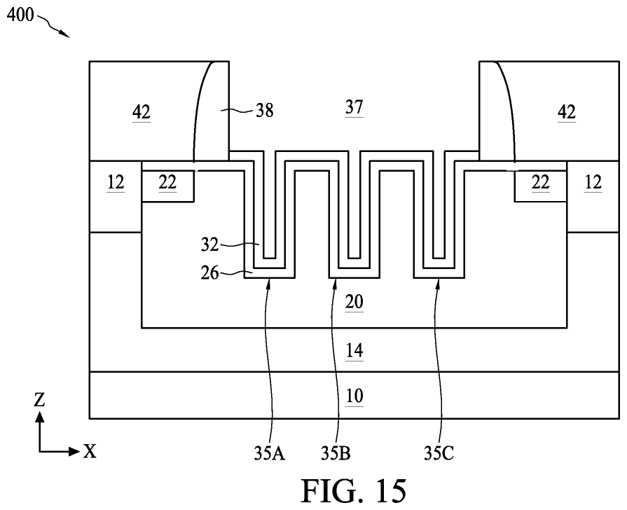

Referring to FIGS. 10A and 15, an interlayer dielectric (ILD) layer 42 is formed over the dummy gate structure 35 and the source/drain regions 22 at operation 316.

The ILD layer 42 may include any suitable dielectric material, such as silicon oxide, a low-k dielectric material, phosphosilicate glass (PSG), borosilicate glass (BSG), boron-doped phosphosilicate glass (BPSG), undoped silicate glass (USG), the like, or combinations thereof, and may be deposited by any suitable method, such as CVD, PECVD, FCVD, or the like. Subsequently, a planarization process, such as a CMP process, is implemented to remove portions of the ILD layer 42 from a top surface of the dummy gate structure 35, such that the ILD layer 42 remains over sidewalls of the gate spacers 38 and top surfaces of the source/drain regions 22.

In some embodiments, prior to forming the ILD layer 42, a contact etch stop layer (CESL; not depicted) is formed over the semiconductor device 400. The ILD layer 42 and the CESL include different materials to provide etching selectivity therebetween in subsequent fabrication processes. The CESL may include any suitable dielectric material such as silicon nitride, silicon oxynitride, silicon oxide, the like, or combinations thereof, and may be formed by a suitable formation method such as CVD, ALD, PVD, the like, or combinations thereof.

Referring to FIGS. 10A and 15, the dummy gate structure 35 is removed from the semiconductor device 400, resulting in a gate trench 37 between the gate spacers 38 at operation 318.

In some embodiments, the dummy gate structure 35 is removed by one or more etching process, such as a dry etching process or a wet etching process, to form the gate trench 37 between the gate spacers 38. In this regard, the bottom portions 35A-35C are partially removed to expose the first dielectric layer 32 in the trenches 24A-24C. In some embodiments, the first dielectric layer 32 is used as an etch stop layer when the dummy gate electrode 33 is etched. In the present embodiments, the first dielectric layer 32 remains in the trenches 24A-24C as depicted in FIG. 15.

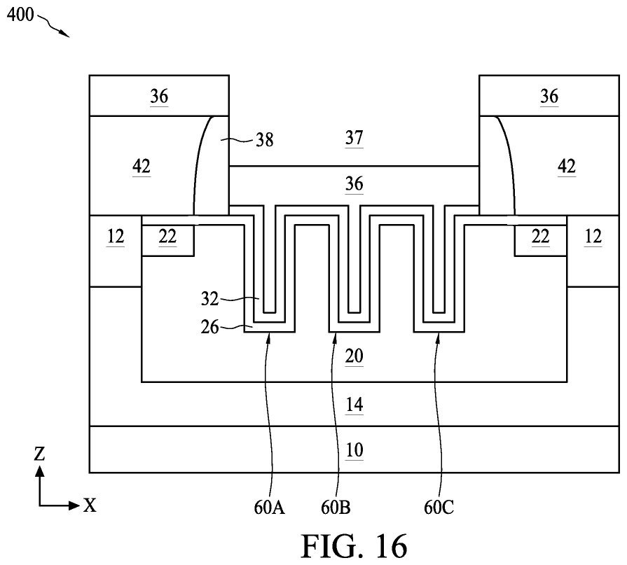

In some embodiments, the method 300 continues with the formation of the semiconductor device 400 by proceeding from operation 318 to operation 330 as depicted in FIG. 10B. Referring to FIGS. 10B and 16, the metal structure 36 is formed over the first dielectric layer 32 to partially fill the gate trench 37 at operation 330.

In the present embodiments, bottom portions of the metal structure 36 are formed over the first dielectric layer 32 to completely fill the trenches 24A-24C, while a top portion of the metal structure 36 is formed in, without completely filling, the gate trench 37. The bottom portions of the metal structure 36, the first dielectric layer 32, and the silicide layer 26 in the trenches 24A-24C form the embedded structures 60A-60C, respectively, similar to that depicted in FIG. 7. In addition, portions of the metal structure 36 are formed over a top surface of the ILD layer 42.

In the present embodiments, the metal structure 36 is configured as a metal gate structure. Accordingly, the metal structure 36 includes at least a metal gate electrode. In some embodiments, the metal gate structure further includes one or more work function metal layers, each having a compound metal or a single metal. Various layers of the metal structure 36 may be formed by any suitable deposition process, such as CVD, PVD, ALD, plating (e.g., electroplating, electroless plating, etc.), the like, or combinations thereof.

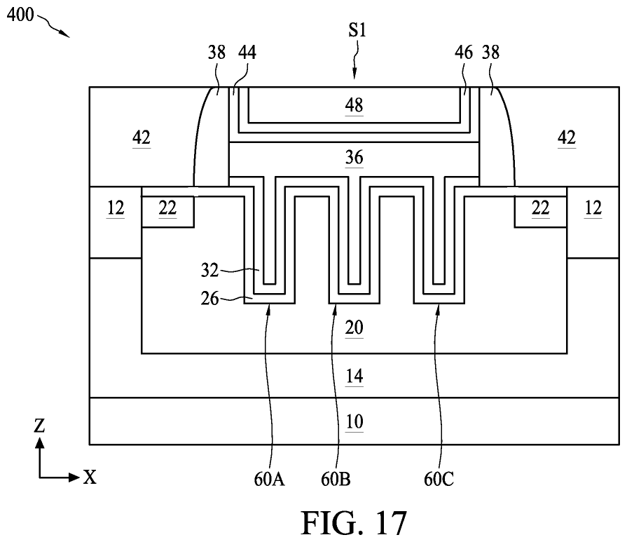

Referring to FIGS. 10B and 17, the second dielectric layer 46 is formed over a portion of the metal structure 36 in the gate trench 37 at operation 332.

In the present embodiments, the second dielectric layer 46 is deposited as a blanket layer (not depicted) over the semiconductor device 400. For example, portions of the second dielectric layer 46 are formed conformally over the metal structure 36 in the gate trench 37, and portions of the second dielectric layer 46 are formed over the ILD layer 42. In this regard, the second dielectric layer 46 and the metal structure 36 partially fill the gate trench 37, and portions of the second dielectric layer 46 are formed along sidewalls of the gate spacers 38. The second dielectric layer 46 may be formed by any suitable deposition technique, such as CVD, ALD, PVD, the like, or combinations thereof.

In some embodiments, the interfacial layer 44 is formed over the metal structure 36 before forming the second dielectric layer 46. Similar to the second dielectric layer 46, the interfacial layer 44 is deposited as a blanket layer (not depicted) over the semiconductor device 400, such that portions of the interfacial layer 44 are formed conformally over the metal structure 36 in the gate trench 37, and portions of the interfacial layer 44 are formed over the ILD layer 42. In this regard, portions of the interfacial layer 44 are formed along the sidewalls of the gate trench 37 between sidewalls of the second dielectric layer 46 and sidewalls of the gate spacers 38. The second dielectric layer 46 may be formed by any suitable deposition technique, such as CVD, ALD, PVD, the like, or combinations thereof.

Referring to FIGS. 10B and 17, a conductive structure 48 is formed over the second dielectric layer 46 to fill the gate trench 37 at operation 334.

In some embodiments, the conductive structure 48 is configured as a metal gate structure, similar to the metal structure 36 described in detail above. In the present embodiments, the conductive structure 48 is formed as a blanket layer (or layers; not depicted) over the semiconductor device 400. For example, portions of the conductive structure 48 are formed over the second dielectric layer 46 to completely fill the gate trench 37, and portions of the conductive structure 48 are formed over the second dielectric layer 46 on the top surface of the ILD layer 42. In this regard, after forming the conductive structure 48, a CMP process is performed to planarize the conductive structure 48, the second dielectric layer 46, and the interfacial layer 44 with the top surface of the ILD layer 42, as depicted in FIG. 17. Accordingly, in the resulting stack S1, the second dielectric layer 46 and the interfacial layer 44 are configured to have a U shape, each surrounding bottom and sidewall surfaces of the conductive structure 48.

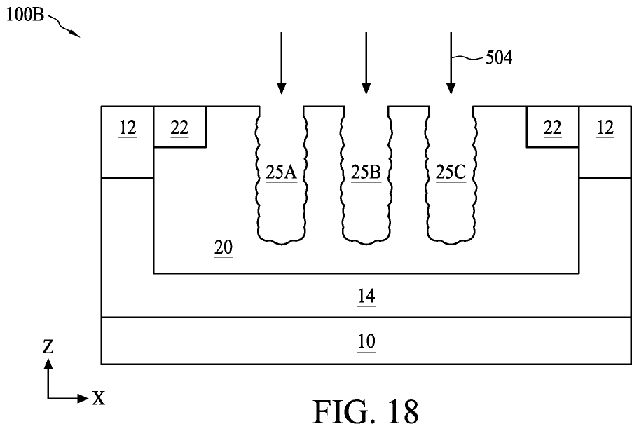

In some embodiments, referring to FIGS. 18, instead of forming the trenches 24A-24C at operation 306, where sidewalls of the trenches 24A-24C are substantially smooth and vertical, trenches 25A-25C are formed at operation 306 using an etching process 504 different from the etching process 502. For example, after forming a patterned mask layer over the doped layer 20 between the source/drain regions 22, the etching process 504 utilizing a periodically oscillating plasma of different compositions is performed to create roughness along sidewall and bottom surface of the trenches 25A-25C. In some embodiments, performing the etching process 504 includes alternating applications of an etching gas (i.e., a first plasma) and a protective gas (i.e., a second plasma) over the semiconductor device 400. The etching gas is configured to remove portions of the doped layer 20 to form and deepen the trenches 25A-25C, while the protective gas is configured to deposit a polymeric (or passivating) layer over the etched surfaces (e.g., sidewall surfaces) of the trenches 25A-25C. The etching gas and the protective gas are applied cyclicly to deepen the trenches 25A-25C, resulting in surfaces exposed in the trenches 25A-25C to exhibit roughness. In some embodiments, the surface roughness increases surface area of the doped layer 20 exposed in the trenches 25A-25C, which in turn increases the surface area of the embedded structures 62A-62C formed in the trenches 25A-25C, respectively, similar to the semiconductor device 100B depicted in FIG. 9.

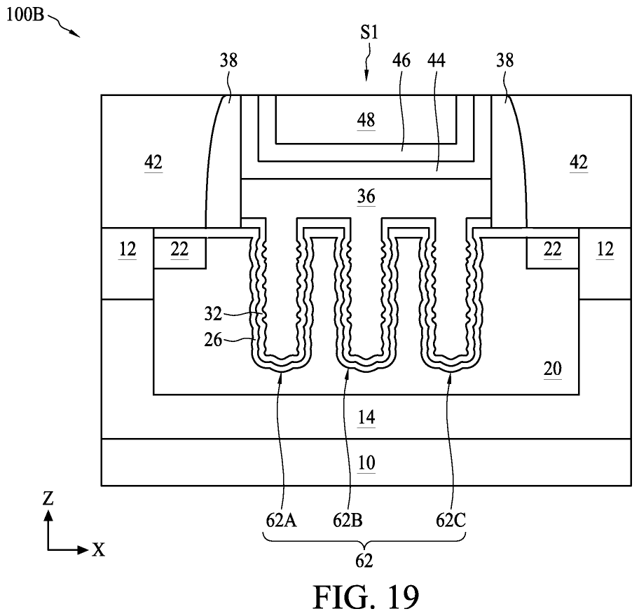

Subsequently, operations 308-318 and 330-334 are performed in a manner similar to those described above, resulting in the semiconductor device 400 that includes the embedded structures 62A-62C, corresponding to the trenches 25A-25C, respectively, as depicted in FIG. 19. In the present embodiments, the embedded structures 62A-62C, collectively referred to as the embedded structure 62, each include the bottom portions of the silicide layer 26, the first dielectric layer 32, and the metal structure 36.

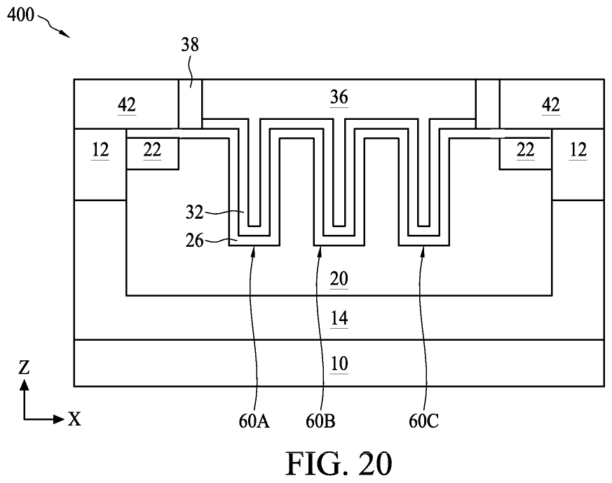

In some embodiments, the method 300 continues with the formation of the semiconductor device 400 by proceeding from operation 318 to operation 350 as depicted in FIG. 10C. Referring to FIGS. 10C and 20, the metal structure 36 is formed over the first dielectric layer 32 to completely fill the gate trench 37 at operation 350.

In the present embodiments, the metal structure 36 is formed in a process similar to that described above with respect to the operation 330. For example, the bottom portions of the metal structure 36 are formed over the first dielectric layer 32 to completely fill the trenches 24A-24C, resulting in the embedded structures 60A-60C, respectively, extending into the doped layer 20 and interposed between the source/drain regions 22 along the lateral direction. However, different from the operation 330, the top portion of the metal structure 36 completely fills the gate trench 37. In this regard, a process of depositing the metal structure 36 is terminated when a blanket layer (not depicted) of the metal structure 36 completely fills the gate trench 37. The metal structure 36 is subsequently planarized with the ILD layer 42 by a CMP process, as depicted in FIG. 20.

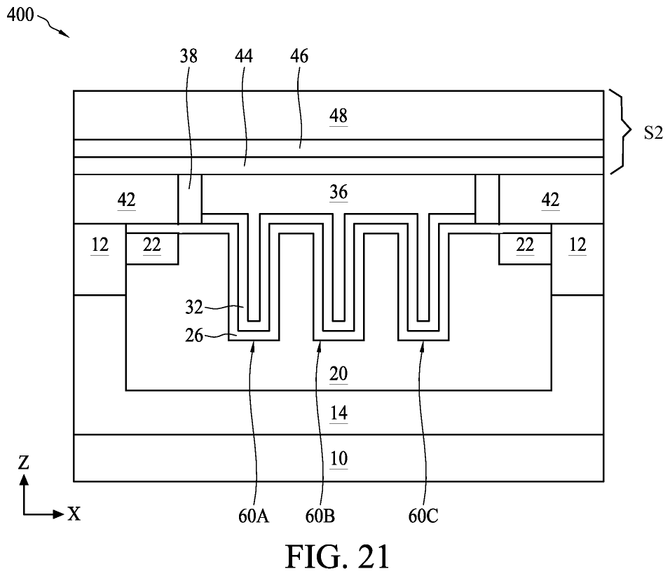

Referring to FIGS. 10C and 21, the second dielectric layer 46 is formed over the metal structure 36 and the ILD layer 42 at operation 352.

In the present embodiments, the second dielectric layer 46 is deposited over the metal structure 36 and the ILD layer 42 as a blanket layer. In some embodiments, the interfacial layer is deposited over the metal structure 36 and the ILD layer 42 before depositing the second dielectric layer 46. The second dielectric layer 46 and the interfacial layer 44 may be formed in a process similar to that described above with respect to the operation 332.

Referring to FIGS. 10C and 21, the conductive structure 48 is formed over the second dielectric layer 46 at operation 354, resulting in the stack S2. In the present embodiments, the conductive structure 48 is formed over the second dielectric layer 46 as a blanket layer by a process similar to that described above with respect to the operation 334.

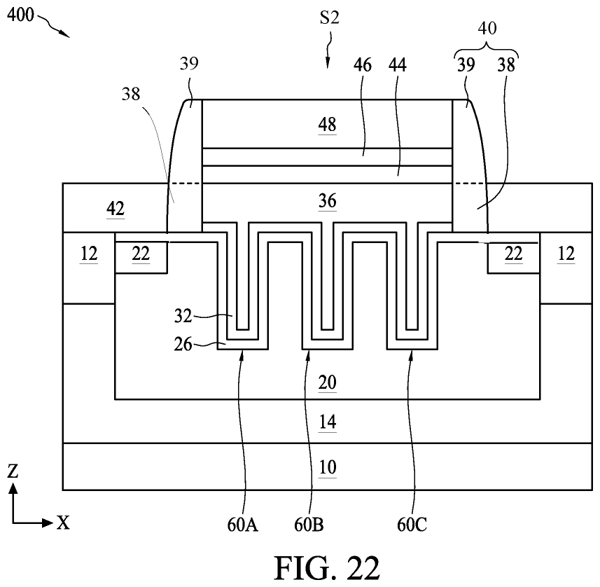

Referring to FIGS. 10C and 22, the stack S2 is patterned, such that their sidewalls are aligned with those of the underlying metal structure 36 at operation 356.

In some embodiments, the stack S2 including the conductive structure 48 and the second dielectric layer 46, as well as the interfacial layer 44, is patterned by a series of photolithography and etching processes. For example, a patterned mask layer (not depicted) including openings corresponding to portions of the stack S2 to be removed is formed over the semiconductor device 400. The method of forming such a patterned mask layer is similar to that described above with respect to forming the doped layer 20. Portions of the stack S2 are then removed by a suitable etching process, such as a dry etching process (or plasma etching process), using the patterned mask layer as an etch mask. The etching process is terminated when the underlying ILD layer 42 is exposed. After patterning the stack S2, the patterned mask layer is removed from the semiconductor device 400 by any suitable process, such as plasma ashing or resist stripping.

Referring to FIGS. 10C and 22, the gate spacers 39 are subsequently formed along the sidewalls of the patterned stack S2, which includes the patterned conductive structure 48, the patterned second dielectric layer 46, and the patterned interfacial layer 44, at operation 358, such that the gate spacers 39 vertically extend from the gate spacers 38. In this regard, the gate spacer 38 and the gate spacers 39 are together referred to as the gate spacers 40.

In some embodiments, the gate spacers 39 are configured as a dielectric seal surrounding sidewalls of the patterned conductive structure 48, the patterned second dielectric layer 46, and the patterned interfacial layer 44, thereby isolating the layers from subsequently formed features. In this regard, the gate spacers 39 may alternatively be referred to as dielectric seals 39. In some embodiments, the gate spacers 39 and the gate spacers 38 have the same composition. In some embodiments, the gate spacers 39 and the gate spacers 38 have different compositions. The gate spacers 39 may be formed by a process similar to that of forming the gate spacers 38 at the operation 314.

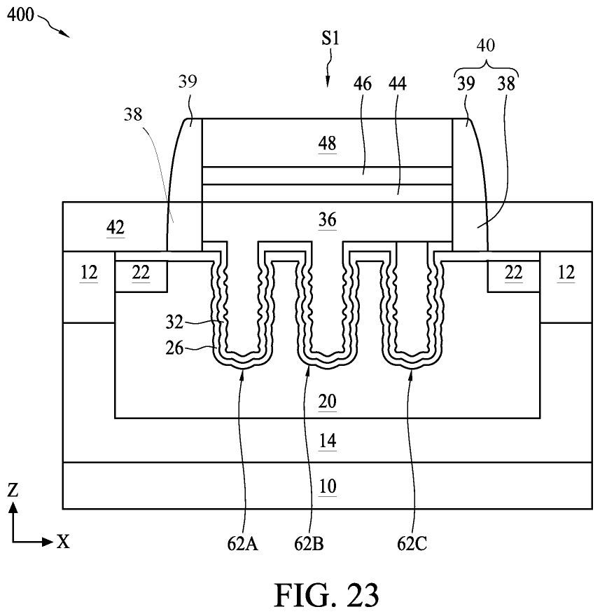

For embodiments in which the trenches 25A-25C are formed by the etching process 504 at the operation 306, as depicted in FIG. 18, the operations 308-318 and 350-358 are subsequently implemented in a manner similar as described above to form the semiconductor device 400 that includes the embedded structures 62A-62C, as depicted in FIG. 23.

In some embodiments, though not depicted, the operation 306 is omitted, such that no trenches are formed in the doped layer 20. In other words, the subsequent layers (e.g., the silicide layer 26, the first dielectric layer 32, the metal structure 36, and the conductive structure 48) are formed entirely over a top surface of, rather than partially being embedded within, the doped layer 20. An example embodiment without any trenches is depicted in FIG. 2, which corresponds to the embodiment of the semiconductor device 400 formed by the operations 308-318 and 330-334, and in FIG. 3, which corresponds to the embodiment of the semiconductor device 400 formed by the operations 308-318 and 350-358.

In the present embodiments, the embodiment of the semiconductor device 400 depicted in FIG. 17 (with the optional doped layers 11 omitted for purposes of simplicity) corresponds to the semiconductor device 100B in FIG. 7; the embodiment of the semiconductor device 400 depicted in FIG. 19 corresponds to the semiconductor device 100B in FIG. 9; and the embodiment of the semiconductor device 400 depicted in FIG. 22 corresponds to the semiconductor device 100B in FIG. 8.

Additional operations may be performed after performing the method 300 as depicted in FIGS. 10A-10C. For example, an additional ILD layer (not depicted) may be formed over the conductive structure 48 and the ILD layer 42. Furthermore, various contacts, such as the substrate contact 50, the source/drain contacts 54A and 54B, the gate contacts 58A, and the gate contact 58B, are formed to electrically couple to a portion of doped well 14, the source/drain regions 22, and the metal structure 36, and the conductive structure 48, respectively.

One aspect of this description relates to a semiconductor structure. The semiconductor structure includes a substrate and a silicide layer over the substrate. The semiconductor structure includes a first dielectric layer over the silicide layer. The semiconductor structure includes a first metal structure over the first dielectric layer. The semiconductor structure includes a second dielectric layer over the first metal structure. The semiconductor structure further includes a conductive structure over the second dielectric layer.

Another aspect of this description relates to a semiconductor structure. The semiconductor structure includes a substrate and a capacitor over the substrate. The capacitor includes a silicide layer over the substrate. The capacitor includes a first dielectric layer over the silicide layer. The capacitor includes a metal gate structure over the first dielectric layer, where a top portion of the metal gate structure is over the substrate and a bottom portion of the metal gate structure extends into the substrate. The capacitor includes a second dielectric layer over the metal gate structure. The capacitor further includes a metal structure over the second dielectric layer.

Another aspect of this description relates to a method of fabricating a semiconductor structure. The method includes providing a substrate including a doped region. The method includes patterning the doped region to form trenches. The method includes forming a silicide layer in the trenches. The method includes forming a first dielectric layer over the silicide layer. The method includes forming a dummy gate over the first dielectric layer, the dummy gate having a bottom portion filling the trenches and a top portion over the bottom portion. The method includes forming gate spacers along sidewalls of the dummy gate. The method includes replacing the dummy gate with a metal gate. The method includes forming a second dielectric layer over the metal gate. The method further includes forming a metal structure over the second dielectric layer.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor structure, comprising:
a substrate;
a silicide layer over the substrate;
a first dielectric layer over the silicide layer;
a metal structure over the first dielectric layer, wherein the metal structure includes a gate electrode;
a second dielectric layer over the metal structure; and
a conductive structure over the second dielectric layer.

2. The semiconductor structure of claim 1, wherein the metal structure includes a first portion over the substrate and a plurality of second portions embedded in the substrate.

3. The semiconductor structure of claim 2, wherein the silicide layer and the first dielectric layer are between the first portion of the metal structure and the substrate, and between the plurality of second portions of the metal structure and the substrate.

4. The semiconductor structure of claim 2, wherein the substrate includes a doped region that embeds the plurality of second portions.

5. The semiconductor structure of claim 2, wherein each of the plurality of second portions of the metal structure has a roughened surface.

6. The semiconductor structure of claim 1, wherein the second dielectric layer traverses both a bottom surface and a sidewall surface of the conductive structure.

7. The semiconductor structure of claim 1, wherein the second dielectric layer traverses only a bottom surface but not a sidewall surface of the conductive structure.

8. The semiconductor structure of claim 1, further comprising a spacer along a sidewall of the metal structure and the conductive structure.

9. A semiconductor structure, comprising:
a substrate; and
a capacitor over the substrate, comprising:
a silicide layer over the substrate;
a first dielectric layer over the silicide layer;
a metal gate structure over the first dielectric layer, wherein a top portion of the metal gate structure is over the substrate and a bottom portion of the metal gate structure extends into the substrate;
a second dielectric layer over the metal gate structure; and
a conductive structure over the second dielectric layer.

10. The semiconductor structure of claim 9, wherein the bottom portion of the metal gate structure includes at least one column structure surrounded by the first dielectric layer and the silicide layer.

11. The semiconductor structure of claim 9, wherein the bottom portion of the metal gate structure has a rough surface.

12. The semiconductor structure of claim 9, wherein the metal gate structure includes at least one work function metal layer.

13. The semiconductor structure of claim 9, wherein the second dielectric layer includes a high-k dielectric material.

14. The semiconductor structure of claim 9, further comprising a third dielectric layer between the metal gate structure and the second dielectric layer, the third dielectric layer having a composition different from the second dielectric layer.

15. The semiconductor structure of claim 9, wherein the substrate includes:
a doped region that surrounds the bottom portion of the metal gate structure; and
source/drain regions disposed in the doped region, wherein the bottom portion of the metal gate structure is interposed between the source/drain regions, and wherein the silicide layer extends over the source/drain regions.

16. A method of fabricating a semiconductor structure, comprising:
providing a substrate including a doped region;
patterning the doped region to form trenches;
forming a silicide layer in the trenches;
forming a first dielectric layer over the silicide layer;
forming a dummy gate over the first dielectric layer, the dummy gate having a bottom portion filling the trenches and a top portion over the bottom portion;
forming gate spacers along sidewalls of the dummy gate;
replacing the dummy gate with a metal gate;
forming a second dielectric layer over the metal gate; and
forming a conductive structure over the second dielectric layer.

17. The method of claim 16, wherein replacing the dummy gate includes:
removing the dummy gate to form a gate trench between the gate spacers; and
partially filling the gate trench with the metal gate such that forming the second dielectric layer forms portions of the second dielectric layer along sidewalls of the gate spacers in the gate trench and forming the conductive structure subsequently fills the gate trench.

18. The method of claim 17, wherein partially filling the gate trench with the metal gate includes:
forming a work function metal layer over the first dielectric layer, and
forming a gate electrode over the work function metal layer.

19. The method of claim 16, wherein the gate spacers are first gate spacers, and wherein the second dielectric layer and the conductive structure are formed across top surfaces of the first gate spacers, the method further comprising:
etching the conductive structure and the second dielectric layer; and
forming second gate spacers along sidewalls of the etched conductive structure and the etched the second dielectric layer such that the second gate spacers extend from the first gate spacers.

20. The method of claim 16, further comprising forming source/drain regions in the doped region, wherein the trenches are formed in a portion of the doped region interposed between the source/drain regions.
